(19) United States
(12) Patent Application Publication
(10) Pub. No.: US 2019/0237501 A1
(43) Pub. Date: Aug. 1, 2019

(54) SEMICONDUCTOR DEVICE AND MANUFACTURING METHOD THEREOF

(71) Applicant: HUAIAN IMAGING DEVICE MANUFACTURER CORPORATION, HUAIAN (CN)

(72) Inventors: Yuping MU, HUAIAN (CN); Shijie CHEN, HUAIAN (CN); Kishou KANEKO, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/010,240

(22) Filed: Jun. 15, 2018

(30) Foreign Application Priority Data
Jan. 30, 2018 (CN) 201810086147.5

(51) Int. Cl. H01L 27/146

(52) U.S. Cl. CPC H01L 27/14629; H01L 27/14643; H01L 27/14685; H01L 27/14689; H01L 27/14623

(57) ABSTRACT

A semiconductor device comprises an array of photosensitive elements and a grid. The grid is arranged on the array of photosensitive elements, defines an opening for receiving light respectively for each photosensitive element, and optically isolates each photosensitive element from its adjacent photosensitive elements. The grid may comprise an optical isolation portion and a dielectric portion above the optical isolation portion, wherein the dielectric portion defines a sidewall tilted at an angle toward an outer side of the opening. Methods of manufacturing semiconductor devices are also disclosed.

### CROSS-REFERENCE TO RELATED APPLICATIONS

The present application claims a priority to a Chinese patent application No. 201810086147.5 that was filed on Jan. 30, 2018, which is herein incorporated by reference.

### TECHNICAL FIELD

The present disclosure relates to the technical field of semiconductor, and more particularly, to a semiconductor device and a manufacturing method thereof.

### BACKGROUND

Image sensors can be used for sensing radiation (e.g., light radiation, including but limited to visible light, infrared light, ultraviolet light, etc.). As for an image sensor, with the increase of a pixel density, the size of each pixel decreases, and an area of a photosensitive element in each pixel for receiving a light signal decreases as well. As a result, there are fewer photo-generated carriers obtained by conversion, the output signal becomes smaller, and the signal-to-noise ratio becomes smaller.

### SUMMARY

One of objects of the present disclosure is to provide a technology capable of improving the utilization of the incident light of the image sensor, and thereby improving quantum efficiency signal-to-noise ratio of the image sensor and so on.

A first aspect of this disclosure is to provide a semiconductor device comprising an array of photosensitive elements and a grid. The grid is arranged on the array of photosensitive elements, defines an opening for receiving light respectively for each photosensitive element, and optically isolates each photosensitive element from adjacent photosensitive elements thereof. The grid comprises an optical isolation portion and a dielectric portion above the optical isolation portion, wherein the dielectric portion defines a sidewall tilted at an angle toward an outer side of the opening.

A second aspect of this disclosure is to provide a method of manufacturing a semiconductor device comprising: forming an array of photosensitive elements in a semiconductor substrate; and forming a grid on the array of photosensitive elements in the semiconductor substrate, wherein the grid defines an opening for receiving light respectively for each photosensitive element, and optically isolates each photosensitive element from adjacent photosensitive elements thereof, wherein the grid comprises an optical isolation portion and a dielectric portion above the optical isolation portion, wherein the dielectric portion defines a sidewall tilted at an angle toward an outer side of the opening.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference to the accompanying drawings.

FIG. 1 is a schematic diagram illustrating the structure of a semiconductor device in the related technologies.

FIG. 2 is a schematic diagram illustrating the structure of a semiconductor device according to one or more embodiments of this disclosure, wherein the top portion of the dielectric portion has a trapezoidal cross section.

FIG. 3 is a flowchart illustrating a method of manufacturing a semiconductor device according to one or more embodiments of this disclosure.

FIG. 4A to 4E are schematic diagrams illustrating examples of the cross sections of the semiconductor device at the steps of manufacturing the semiconductor device as shown in FIG. 2.

FIG. 5A to 5D are schematic diagrams illustrating other examples of the cross sections of the semiconductor device at the steps of manufacturing the semiconductor device as shown in FIG. 2.

FIG. 6 is a schematic diagram illustrating the structure of a semiconductor device according to one or more embodiments of this disclosure.

FIG. 7 is a schematic diagram illustrating the structure of a semiconductor device according to one or more embodiments of this disclosure.

FIG. 8 is a schematic diagram illustrating the structure of a semiconductor device according to one or more embodiments of this disclosure, wherein the top portion of the dielectric portion has a triangular cross section.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present disclosure unless it is specifically stated otherwise.

The following description of at least one exemplary embodiment is merely illustrative in nature and is in no way intended to limit this disclosure, its application, or uses.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

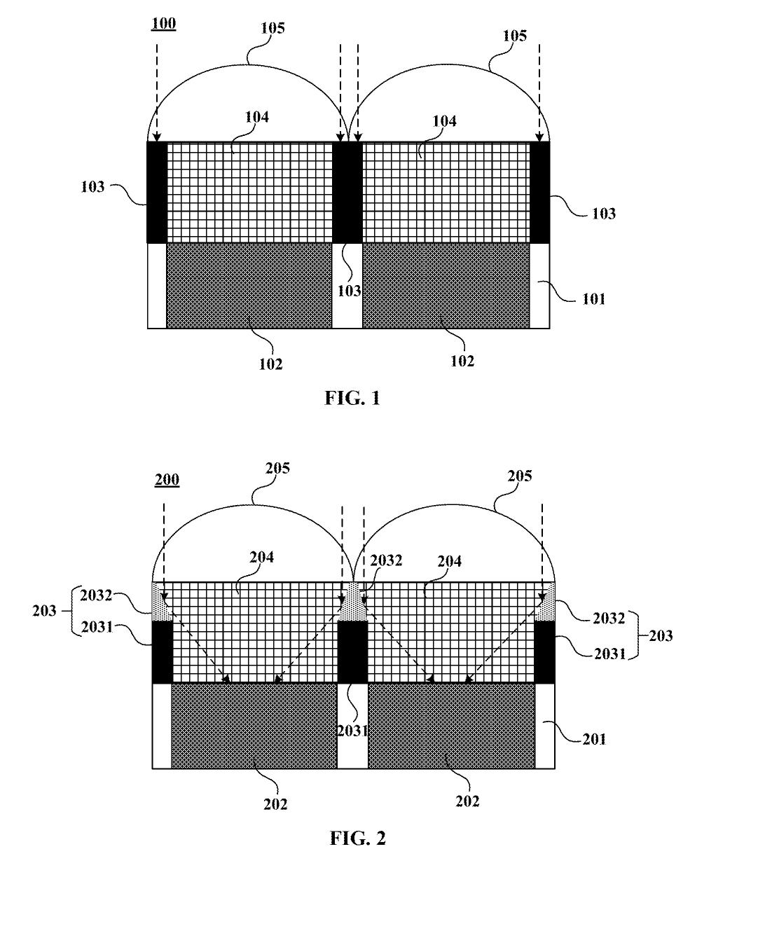

FIG. 1 is a schematic diagram illustrating the structure of an image sensor in the related technologies. The image sensor 100 in the related technologies comprises a semiconductor substrate 101, an array of photosensitive elements 102 formed in the semiconductor substrate 101 and a grid 103 formed on the substrate 101 and the photosensitive elements 102. Each photosensitive element 102 corresponds to one pixel of the image sensor 100. The grid 103 defines an opening for receiving light respectively for each photosensitive element 102, and is used for optically isolating adjacent two photosensitive elements 102, so that the light entering the opening of one photosensitive element 102 will not enter its adjacent photosensitive elements 102. In addition, an optical material 104 can be filled in the opening. For example, the optical material 104 may include filter materials (for example, various dyes, paints, pigments) used for filtering the light entering the opening, thereby extracting the filtered wavelength. In general, the filter materials in adjacent pixels can respectively correspond to, for example, the three primary colors R, G, B, thereby forming a color image sensor 100. In addition, the optical material 104 can further include a dielectric material, for filling the opening, protecting the photosensitive elements 102 and the grid 103, etc. In addition, the optical material 104 can also be any optical material occurring to a person skilled in the art. Finally, above the optical material 104, the image sensor 100 may further comprise a microlens 105, for converging and collimating the incident light, etc.

As shown in FIG. 1, the cross section of the grid 103 of the image sensor 100 in the related technologies is rectangular and has a top surface with a certain width. Therefore, the light incident to the top surface of the grid 103 (for example, shown by dashed lines with an arrow in the figure) will be blocked by the top surface, and thus cannot reach the photosensitive element 102, and cannot be utilized.

FIG. 2 is a schematic diagram illustrating the structure of a semiconductor device 200 according to an embodiment of this disclosure. As shown in FIG. 2, the semiconductor device 200 according to the embodiment of this disclosure comprises a semiconductor substrate 201, an array of photosensitive elements 202 formed in the semiconductor substrate 201 and a grid 203 formed on the substrate 201 and the photosensitive elements 202. The substrate 201 can be made of a single-element semiconductor material (such as silicon or germanium) or a compound semiconductor material (such as silicon carbide, silicon germanium, gallium arsenide, gallium phosphide, indium phosphide, indium arsenide and/or indium stibide) or a combination thereof. A photosensitive element 202 for sensing light can be formed in the substrate of the semiconductor device according to the embodiment of this disclosure, so the semiconductor device can be configured as an image sensor, and each photosensitive element 202 corresponds to one pixel of the image sensor. The grid 203 defines an opening for receiving light respectively for each photosensitive element 202, and optically isolates each photosensitive element 202 from its adjacent photosensitive element 202, so that the light entering the opening of one photosensitive element 202 will not enter its adjacent photosensitive elements 202. In addition, an optional optical material 204 can be filled in the opening. For example, the optical material 204 may include a filter material, a dielectric material and any optical material occurring to a person skilled in the art. Finally, above the optical material 204, the semiconductor device 200 may optionally further comprise a microlens 205, for converging and collimating the incident light, etc.

As shown in FIG. 2, the grid 203 according to the embodiment of this disclosure comprises an optical isolation portion 2031 and a dielectric portion 2032 above the optical isolation portion 2031. The optical isolation portion 2031 is made of an opaque material (e.g., metal (e.g., titanium, tungsten or aluminum)), defines an opening for receiving light respectively for each photosensitive element 202, and optically isolates each photosensitive element 202 from its adjacent photosensitive elements 202. The dielectric portion 2032 is made of a dielectric material and defines a sidewall tilted at an angle toward the outer side of the opening. Examples of the dielectric materials for making the dielectric portion 2032 include (but are not limited to): a high K dielectric, a metal oxide, a silicon oxide, a silicon nitride, a silicon nitrogen oxide or oxynitride, a silicon carbide, other oxide materials and nitride materials, etc. Even in the absence of the optical material 204, since the sidewall is tilted at an angle toward the outer side of the opening and reflections occurring on the sidewall are utilized, at least part of the light incident onto the sidewall (for example, shown by the solid lines A and B with an arrowhead) can be reflected towards the surface of the photosensitive element 202. Therefore, an area occupied by the grid 203 on the semiconductor device 200 becomes an area that can receive the incident light, which improves utilization of the incident light, and thereby improves quantum efficiency, signal-to-noise ratio of the image sensor and so on.

The tilt angle of the sidewall can be set by taking into consideration the direction of the incident light, the size of the semiconductor device (e.g., the width of the opening of the grid, the height of the optical isolation portion, etc.) and the refractive index of the dielectric. For example, the angle at which the sidewall is tilted outward from the vertical direction is set to guide the light incident onto the sidewall towards the surface of the photosensitive element. Alternatively, the angle at which the sidewall is tilted outward from the vertical direction is set to less than 45°. This is because, generally speaking, the direction of the incident light primarily is substantially perpendicular to the surface of the photosensitive element (i.e., in the vertical direction), so in this case, if the angle at which the sidewall is tilted outward from the vertical direction is greater than 45°, the light incident along the vertical direction, after being reflected, will move in a direction away from the photosensitive element. When the angle at which the sidewall is tilted outward from the vertical direction is less than 45°, the light incident along the vertical direction, after being reflected, will enter the opening formed by the grid and travel in a direction approaching the photosensitive element. Then, these rays can directly, or indirectly illuminate the surface of the photosensitive element after being reflected from the side surface of the grid, thereby increasing the utilization of the incident light and improving quantum efficiency, signal-to-noise ratio of the image sensor and so on. Of course, for the incident light incident in the other directions, more possibilities and ranges can be considered for the tilt angle of the sidewall.

In addition, the angle at which the sidewall is tilted outward from the vertical direction can be configured so that the reflected light can directly illuminate the photosensitive element. For example, as the tilt angle of the sidewall decreases, more incident light, after beings reflected, will directly illuminate the photosensitive element, so the angle at which the sidewall is tilted outward from the vertical direction is configured to be preferably less than or equal to an angle at which the light incident to a lower end of the sidewall can be directly reflected onto the photosensitive element.

A person skilled in the art could understand that, the shape of the sidewall of the dielectric portion 2032 can be a straight line, a curve, a polyline and other shapes, as long as the tangent of at least a part of the sidewall is tilted at an angle toward the outer side of the opening.

A person skilled in the art could understand that, according to the height and width of the dielectric portion 2032, and the tilt angle of the slope, and the fabrication process adopted, and so on, at the top of the dielectric portion 2032, the slopes on both sides of the dielectric portion 203 can intersect or not intersect each other, such that the top portion of the dielectric portion 2032 has a trapezoidal cross section or a triangular cross section. In this embodiment, the top portion having the trapezoidal cross section is described as an example.

In an embodiment of this disclosure, in case where the optical material 204 is formed in the opening of the grid 203, the refractive index of the optical material 204 is greater than that of the material of the dielectric portion 2032 at an interface between the optical material 204 and the sidewall of the dielectric portion 2032. A person skilled in the art know that, when the light enters an optical thinner medium with a lower refractive index from an optical denser medium with a larger refractive index, if the incident angle is greater than a critical angle at which a total reflection occurs, a total reflection will occur for the incident light on an interface between the two media, that is, the incident light is totally reflected back into the optical denser medium. In this embodiment, by selecting the refractive indexes of the materials on both sides of the interface between the optical material 204 and the dielectric portion 2032 and the angle of the slope, more light incident onto the slope can satisfy the condition of total reflection. For example, when the refractive indexes of the materials on both sides of the interface between the optical material 204 and the dielectric portion 2032 are 2.7 and 1.5 respectively, the calculated critical angle is about 33.7°. When the refractive indexes of the materials on both sides of the interface between the optical material 204 and the dielectric portion 2032 is 2.7 and 1.2 respectively, the calculated critical angle is about 26.4°. It can be seen that, for a slope with a certain angle, the larger a difference between the refractive indexes of the materials on both sides of the interface between the optical material 204 and the dielectric portion 2032 is, the smaller the critical angle of the total reflection becomes, therefore more light incident onto the slope can satisfy the condition of total reflection.

In the case of total reflection, the angle at which the sidewall is tilted outward from the vertical direction can take into account of the critical angle of the total reflection. For example, the angle at which the sidewall is tilted outward from the vertical direction can be set such that the light incident in the vertical direction, after being totally reflected, will enter the opening formed by the grid and travel in a direction approaching the photosensitive element. That is, the angle at which the sidewall is tilted outward from the vertical direction can be set to be less than an angle at which the light incident in the vertical direction, after being totally reflected, travels in a horizontal direction. Further, the angle at which the sidewall is tilted outward from the vertical direction can be set to an angle at which the incident light, after being totally reflected, will be directly incident onto the photosensitive element. That is, the angle at which the sidewall is tilted outward from the vertical direction can be configured to be less than an angle at which the light incident to a lower end of the sidewall can be directly totally reflected onto the photosensitive element.

A person skilled in the art could understand that, the total reflection is a specific condition under which the sidewall reflects the light incident thereon. In the occurrence of a total reflection, the utilization of the incident light can be further improved, so as to further improve quantum efficiency, signal-to-noise ratio of the image sensor and so on.

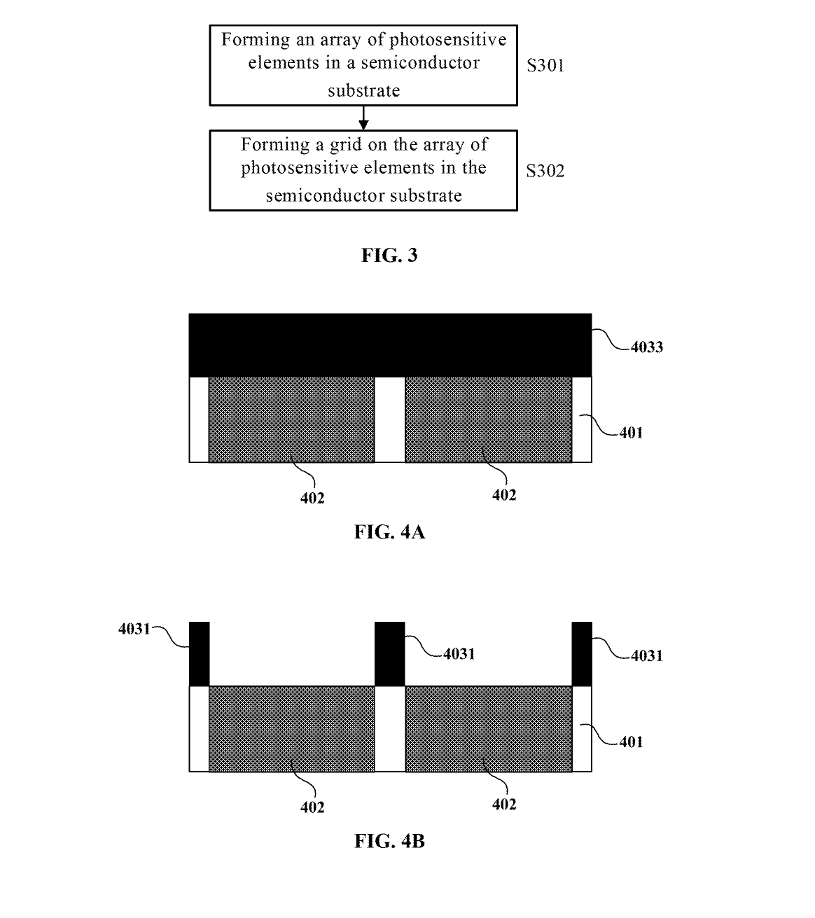

FIG. 3 is a schematic diagram illustrating a method of manufacturing a semiconductor device according to an embodiment of this disclosure. As shown in FIG. 3, an array of photosensitive elements is formed in the semiconductor substrate in a step S301.

This step comprises forming respective photosensitive elements in the semiconductor substrate and forming corresponding conductive wirings, dielectric layers, shallow groove isolation portions, etc., by using various known technologies in the art, and for the sake of clarity, specific descriptions of the step are omitted in this disclosure.

Then, in a step S302, a grid is formed on the array of photosensitive elements in the semiconductor substrate, wherein the grid defines an opening for receiving light respectively for each photosensitive element and isolates each photosensitive element from its adjacent photosensitive elements. As described above, the formed grid comprises an optical isolation portion and a dielectric portion above the optical isolation portion, and the dielectric portion defines a sidewall tilted at an angle toward the outer side of the opening. A person skilled in the art could understand that, any technology or process can be used in the embodiment of this disclosure as long as the above grid structure can be finally obtained, and specific steps of forming the grid structure can be adjusted adaptively according to the technology and process used.

In addition, in the various embodiments of this disclosure, specific steps of forming the grid are different according to the differences of the overall structures and materials of the formed grid and the semiconductor device. The steps of forming the grid according to the various embodiments are described below.

In addition, after the step of forming the grid, as described above, steps of forming the optical material and the microlens and so on are optionally included.

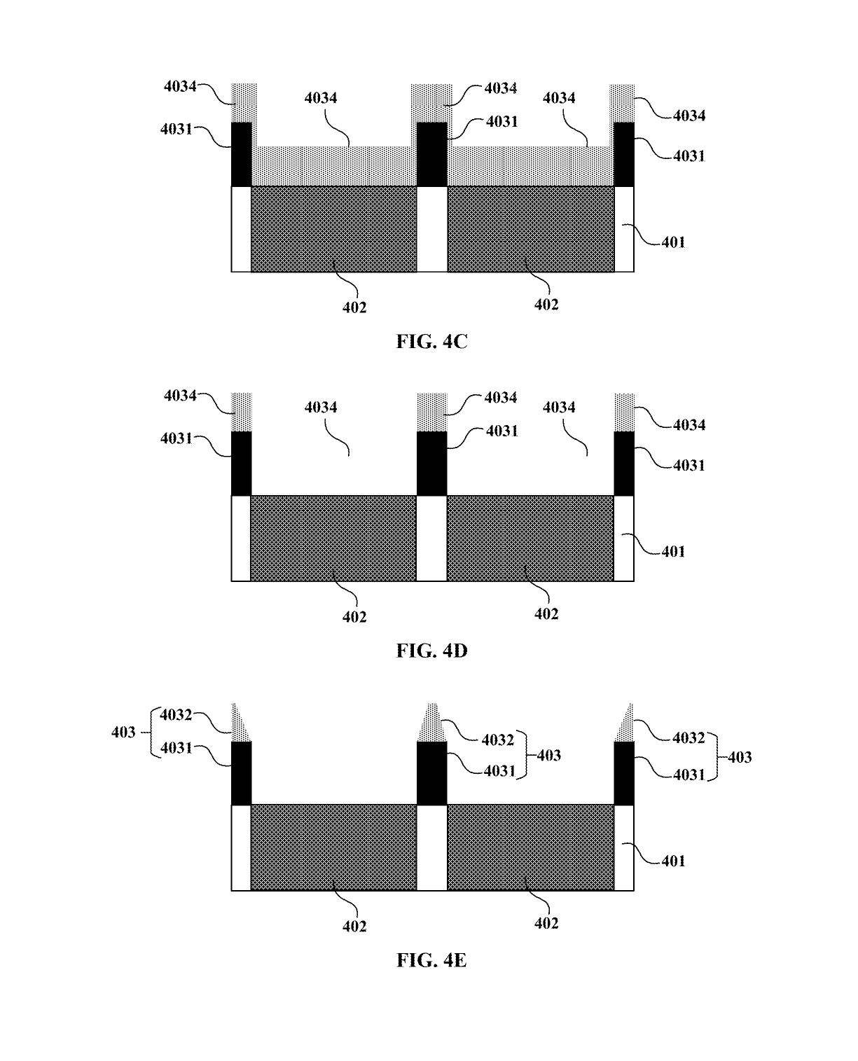

FIG. 4A to 4E are schematic diagrams illustrating examples of the cross sections of the semiconductor device 200 at the steps of manufacturing the semiconductor device as shown in FIG. 2.

First, as shown in FIG. 4A, an array of photosensitive elements 402 is formed in the semiconductor substrate 401 (e.g. through a deposition process, an injection process, etc.). The technologies of forming the photosensitive elements in the semiconductor substrate is known to a person skilled in the art, so the descriptions thereof are omitted here. Thereafter, the step of forming a grid on the semiconductor substrate 401, i.e., forming an optical isolation material layer 4033 on the semiconductor substrate 401, starts. The optical isolation material layer 4033 may be made of opaque materials (e.g. metal, metal alloy, metal compound, etc.). Any suitable process known in this art can be used to form the optical isolation material layer 4033, including but not limited to: physical vapor deposition (PVD), chemical vapor deposition (CVD), atomic layer deposition (ALD), spraying, spin coating, or a combination thereof.

Thereafter, as shown in FIG. 4B, the optical isolation material layer 4033 is subjected to a patterning process to remove a portion of the optical isolation material layer 4033 above the photosensitive element 402, thereby forming an optical isolation portion 4031, and the pattern of the optical isolation portion 4031 corresponds to the pattern of the grid 403 and defines an opening for receiving light for each photosensitive element 402. The patterning process for example can be performed by an etching process through a patterning mask (for example, a photoresist or a hard mask).

Thereafter, as shown in FIG. 4C, a dielectric layer 4034 is formed on the optical isolation portion 4031 and the semiconductor substrate 401. Any suitable process known in the art be used to form the dielectric layer 4034, including but not limited to: physical vapor deposition (PVD), chemical vapor deposition (CVD), atomic layer deposition (ALD), spraying, spin coating, or a combination thereof.

Thereafter, as shown in FIG. 4D, the dielectric layer 4034 is subjected to a patterning process to remove a portion thereof above the photosensitive element 402 and retain a portion thereof above the optical isolation portion 4031.

Next, as shown in FIG. 4E, the portion of the dielectric layer 4034 above the optical isolation portion 4031 is subjected to a patterning process, such that it has a sidewall tilted at an angle toward the outer side of the opening, to thereby form the dielectric portion 4032.

The above patterning process for example can be performed by an etching process through a patterning mask (e.g., a photoresist or a hard mask). Many kinds of techniques for controlling contours of the etching are known to a person skilled in the art. For example, the patterning process described with reference to FIG. 4D can be made by means of anisotropic etching. In addition, the patterning process described with reference to FIG. 4E can be made by means of isotropic etching. For example, through the isotropic etching, the dielectric material is etched from the bottom surface of the mask as the etching continues, to obtain the sidewall of the dielectric layer 4034, which is tilted toward the outer side of the opening.

In addition, in an embodiment of this disclosure, for the patterning process described with reference to FIG. 4E, the sidewall of the dielectric layer 4034, which is tilted toward the outer side of the opening can be obtained, by repeating once or multiple times the isotropic etching and anisotropic etching steps by means of the combination of the isotropic etching and the anisotropic etching. In another embodiment of this disclosure, the mask can be formed or preprocessed so as to make the width of the mask gradually narrower as the etching continues, thereby obtaining the sidewall of the dielectric layer 4034, which is tilted toward the outer side of the opening. In this case, the anisotropic etching can also be used for obtaining the sidewall of the dielectric layer 4034, which is tilted toward the outer side of the opening. For example, a mask material that is comparatively sensitive to the etching process can be selected, such that the mask is also affected by the etching process and gradually becomes narrower as the etching continues. For example, the texture of the mask becomes looser through a mask forming process or a preprocessing, such that the mask is gradually eroded as the etching continues and thus gradually becomes narrower.

In addition, the processes described with reference to FIG. 4D and FIG. 4E can be performed using the same mask. That is, by using the same mask, the process described with reference to FIG. 4D is firstly performed by the anisotropic etching, and the process described with reference to FIG. 4E is then performed by the isotropic etching. In addition, the processes described with reference to FIG. 4D and FIG. 4E can be combined with each other in one step, that is, the structure as shown in FIG. 4E is obtained by repeating once or multiple times the isotropic etching and anisotropic etching steps.

A person skilled in the art could think of a variety of methods of configuring the shape of the sidewall of the dielectric layer to thereby obtain the sidewall tilted toward the outer side of the opening, and all these contents are incorporated into this disclosure.

After the step shown in FIG. 4E, there may comprise a step of forming an optical material and a step of forming a microlens, etc. For the sake of clarity and simplicity, these steps are omitted here.

From the above description in combination with FIG. 4 A to FIG. 4E, a person skilled in the art could obtain a method for manufacturing the semiconductor device as shown in FIG. 2 according to the embodiment of this disclosure.

In addition, a person skilled in the art would appreciate that, the order of the steps of forming the optical isolation portion and dielectric portion as described above can be changed and the semiconductor device 200 shown in FIG. 2 can be also obtained finally.

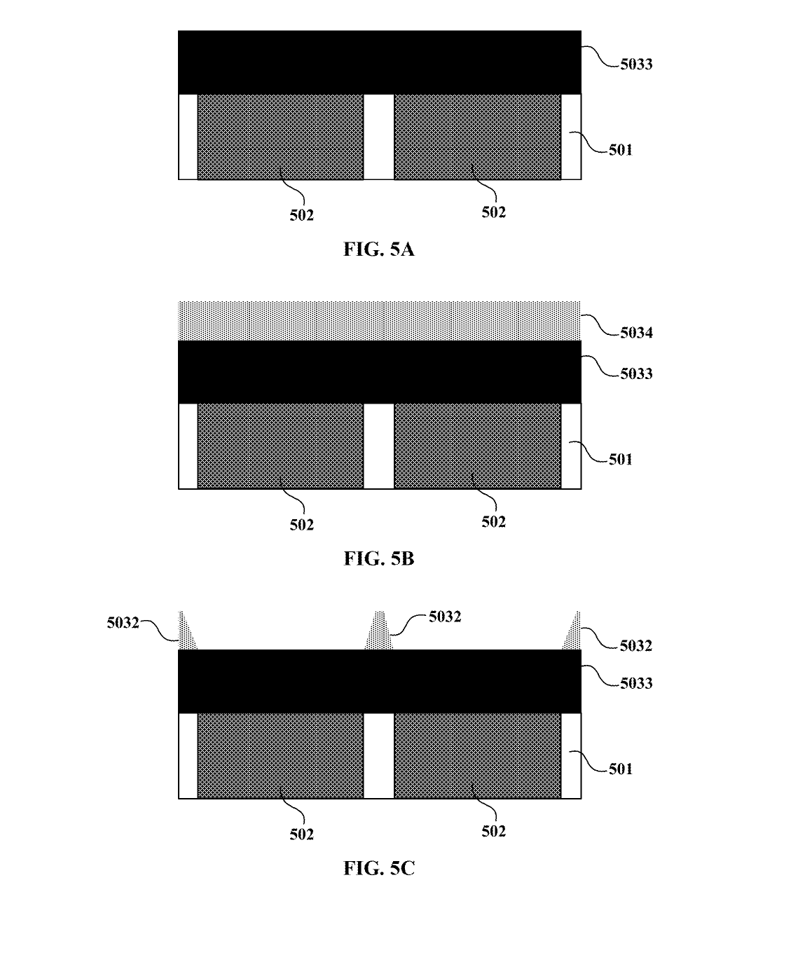

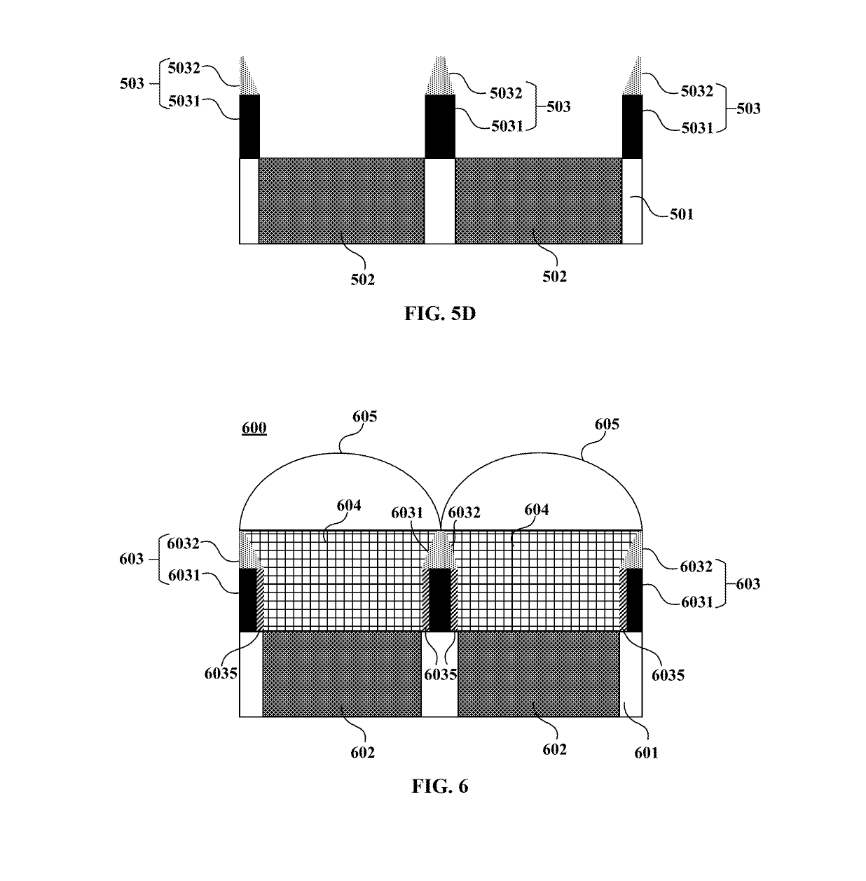

FIG. 5A to 5D are schematic diagrams illustrating other examples of the cross sections of the semiconductor device at the steps of manufacturing the semiconductor device 200 as shown in FIG. 2.

First, similar to FIG. 4A, as shown in FIG. 5A, an array of photosensitive elements 502 is formed in a semiconductor substrate 501 (e.g. through deposition process, injection process, etc.). Thereafter, the step of forming grid on the semiconductor substrate 501 starts, that is, an optical isolation material layer 5033 is formed on the semiconductor substrate 501.

Thereafter, as shown in FIG. 5B, a dielectric layer 5034 is formed on the optical isolation material layer 5033 and the semiconductor substrate 501.

Thereafter, as shown in FIG. 5C, the dielectric layer 5034 is subjected to a patterning process to remove a portion thereof above the photosensitive element 502 and retain a portion thereof above the optical isolation portion 5031, and a sidewall tilted at an angle toward the outer side of the opening is formed to thereby form a dielectric portion 5032.

Thereafter, as shown in FIG. 5D, the optical isolation material layer 5033 is subjected to a patterning process to remove a portion of the optical isolation material layer 5033 above the photosensitive element 502, thereby forming the optical isolation portion 5031, and the pattern of the optical isolation portion 5031 corresponds to the pattern of the grid 503 and defines an opening for receiving light for each photosensitive element 502.

In addition, it can be also as shown in FIG. 5B that, after forming the optical isolation material layer 5033 and the dielectric layer 5034, firstly the optical isolation material layer 5033 and the dielectric layer 5034 are patterned together, to remove portions of the optical isolation material layer 5033 and the dielectric layer 5034 above the photosensitive element 502, thereby forming the optical isolation portion 5031, and retaining the dielectric layer above the optical isolation portion 5031. At this time, the resulting structure is similar to the structure shown in FIG. 4D. Thereafter, similar to FIG. 4E, the retained dielectric layer is subjected to a patterning process such that it forms a sidewall tilted at an angle toward the outer side of the opening, thereby forming the dielectric portion 5032. For the sake of clarity and conciseness of the description, schematic diagrams for these steps are omitted.

From the above description in combination with FIG. 5A to 5D, a person skilled in the art could obtain a method of manufacturing the semiconductor device 200 as shown in FIG. 2 according to the embodiment of this disclosure.

FIG. 6 is a schematic diagram illustrating a structure of a semiconductor device 600 according to another embodiment of this disclosure. As shown in FIG. 6, the semiconductor device 600 according to the embodiment of this disclosure comprises a semiconductor substrate 601, an array of photosensitive elements 602 and a grid 603. In addition, the semiconductor device 600 may further comprise an optical material 604 and a microlens 605. In the following, parts similar to those in the semiconductor device in FIG. 2 are omitted, and only different parts are discussed.

As shown in FIG. 6, the grid 603 according to the embodiment of this disclosure comprises, in addition to the optical isolation portion 6031 and the dielectric portion 6032 above the optical isolation portion 6031, a second dielectric portion 6035 covering a side surface of the optical isolation portion 6031. The second dielectric portion 6035 can isolate the optical isolation portion 6031 from the optical material 604, thereby avoiding the interaction between them. For example, many optical materials may react with the metal material that forms the optical isolation portion 6031, which destroys the optical properties of the optical materials. Thus, the formation of the second dielectric portion 6035 may be advantageous in case where the optical material 604 is formed in the opening of the grid 603.

Similar to the semiconductor device 200 in FIG. 2, thanks to the occurrence of reflection or total reflection on the side surface of the dielectric portion 6032, the semiconductor device 600 according to the embodiment can also improve the utilization of the incident light, and thereby improve quantum efficiency, signal-to-noise ratio of the image sensor and so on.

In an embodiment of this disclosure, the first several steps for manufacturing the sensor 600 are identical with those shown in FIG. 4A to FIG. 4C. However, after the formation of the dielectric layer, when the dielectric layer is subjected to the patterning process, in addition to removing the portion thereof above the photosensitive element 602 and retaining the portion thereof above the optical isolation portion 6031, the portion on the side surface of the optical isolation portion 6031 is also retained, thereby forming a second dielectric portion 6035. A person skilled in the art would appreciate that, in this case, since the second dielectric portion 6035 and the dielectric portion 6032 are actually made of the same dielectric layer, the material of the second dielectric portion 6035 is the same with the material of the dielectric portion 6032.

In another embodiment of this disclosure, between the steps shown in FIG. 4D and FIG. 4E, or after the step shown in the FIG. 5D, the following steps are further comprised: separately forming the second dielectric layer on the optical isolation portion 6031 and the semiconductor substrate 601, and patterning the second dielectric layer, to remove a portion of the second dielectric layer above the photosensitive element 602 and a portion thereof above the optical isolation portion 6031, and retain a portion of the second dielectric layer covering the side surface of the optical isolation portion 6031, thereby forming the second dielectric portion 6035. It can be seen that, since the second dielectric layer is formed separately, its material can be the same with or different from the material of the dielectric portion 6032, and can be determined according to actual needs, which increases flexibility of the design.

However, as compared with the embodiment in which the second dielectric layer is separately formed and patterned to form the second dielectric portion, the embodiment in which both the second dielectric portion and the dielectric portion are formed from the same dielectric layer can reduce steps of the method, simplify the fabrication process, accelerate the manufacturing speed, etc.

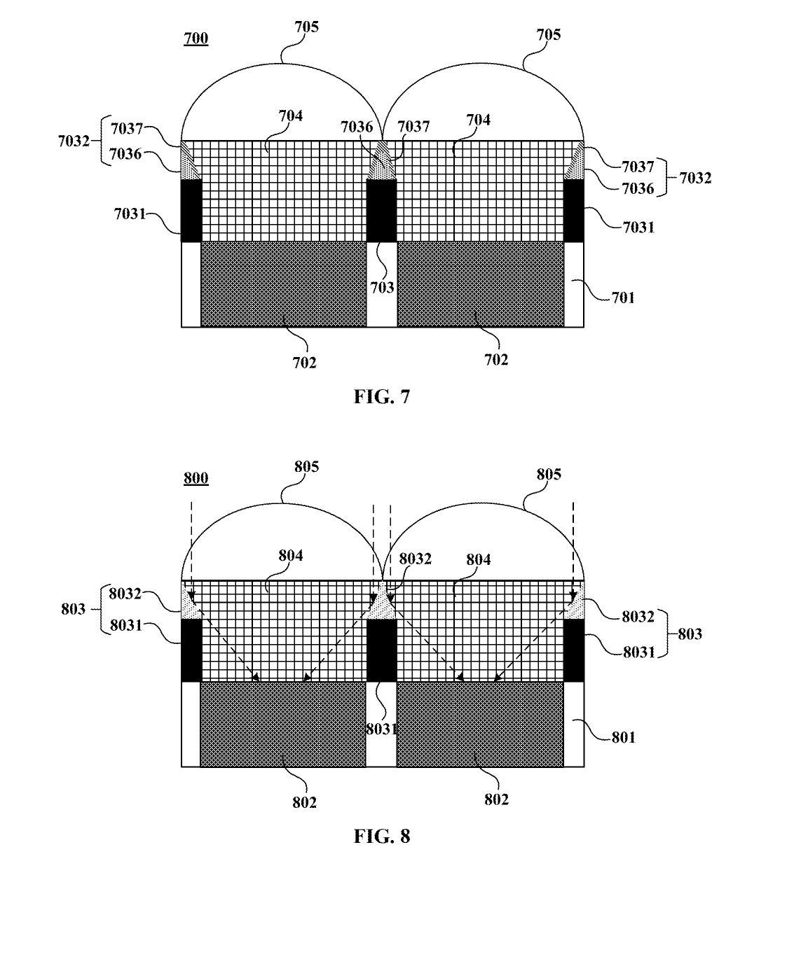

According to another embodiment of this disclosure, FIG. 7 is a schematic diagram illustrating a structure of a semiconductor device 700 according to an embodiment of this disclosure. As shown in FIG. 7, the semiconductor device 700 according to the embodiment of this disclosure comprises a semiconductor substrate 701, an array of photosensitive element 702 and a grid 703. In addition, the semiconductor device 700 can also comprise an optical material 704 and a microlens 705. In the following, parts similar to those in the semiconductor device in FIG. 2 are omitted, and only different parts are discussed.

As shown in FIG. 7, as compared to the semiconductor device 200 shown in FIG. 2, the grid 703 in the semiconductor device 700 according to the embodiment of this disclosure also comprises an optical isolation portion 7031, with an exception that a dielectric portion 7032 above the optical isolation portion 7031 comprises a main body portion 7036 and a covering portion 7037, wherein the covering portion 7037 covers a surface of the main body portion 7036, and the covering portion 7037 and the main body portion 7036 are made of different dielectric materials. In this case, an outer surface of the covering portion 7037 constitutes the sidewall of a dielectric portion 7032, and similar to the semiconductor device 200 shown in FIG. 2, since the sidewall is tilted at an angle toward the outer side of the opening and reflections occurring on the sidewall are utilized, at least part of the light incident onto the sidewall can be reflected towards the surface of the photosensitive element 202. Therefore, an area occupied by the grid 703 on the semiconductor device 700 becomes an area that can receive the incident light, which improves the utilization of the incident light, and thereby improves quantum efficiency, signal-to-noise ratio of the image sensor and so on.

In the semiconductor device 700 shown in FIG. 7, since the dielectric portion 7032 is composed of two parts, and the material forming the reflective interface is the material of the outside covering portion 7037. Therefore, similar to the structure described with reference to FIG. 2, in case where an optical material 704 is formed in the opening of the grid 703, at an interface between the optical material 704 and the sidewall of the dielectric portion 7032, the refractive index of the optical material 704 is greater than the refractive index of the material of the covering portion 7037 and a tilt angle of the sidewall of the dielectric portion 7032 can be configured such that the light incident from the outside of the semiconductor device 700 onto the interface is totally reflected toward the photosensitive element.

For the embodiment of this disclosure, in case where the material of the covering portion 7037 for example is comparatively expensive, and/or it is comparatively difficult and/or time-consuming to form a material layer with the material of the covering portion 7037, by forming the dielectric portion 7032 from both the main body portion 7036 and the covering portion 7037, the thickness of the covering portion 7037 and the amount of the material used can be reduced, thereby reducing the cost of the semiconductor device 700 and/or improving the production efficiency. In addition, by forming the dielectric portion 7032 from both the main body portion 7036 and the covering portion 7037, flexibility of the design can be greatly increased.

Although FIG. 7 shows that the cross sections of both the main body portion 7036 and the covering portion 7037 are of a trapezoidal shape, and the covering portion 7037 is a thin layer covering the main body portion 7036, a person skilled in the art could understand that, the shape of the main body portion and the covering portion is not limited to this. The main body portion and the covering portion can have other shapes, so long as the dielectric portion formed by the combination of them has a sidewall which is composed of the covering portion and is tilted at an angle toward the outer side of the opening.

The steps of manufacturing the semiconductor device 700 as shown in FIG. 7 according to the embodiment are similar to those shown in FIG. 4A to FIG. 4E, with a difference that the formed dielectric portion 7031 comprises the main body portion 7036 and the covering portion 7037. Specifically, when the dielectric layer is subjected to the patterning process, the portion of the dielectric layer above the photosensitive element 702 is removed and the portion thereof above the optical isolation portion 703 is retained, thereby forming the main body portion 7036 of the dielectric portion 7031. After forming the main body portion 7036 of the dielectric portion 7031, a third dielectric layer is formed on the semiconductor substrate 701 and the main body portion 7036 of the dielectric portion 7031. Thereafter, the third dielectric layer is subjected to the patterning process to remove a portion of the third dielectric layer above the photosensitive element 702 and retain a portion thereof above the main body portion 7036 of the dielectric portion 7031, thereby forming the covering portion 7037 of the dielectric portion 7031.

Similarly to FIG. 6, the semiconductor device 700 shown in FIG. 7 may also comprise a second dielectric portion covering a side surface of the optical isolation portion 7031. Similarly to FIG. 6, the second dielectric portion may be formed in the following manner: when the dielectric layer and/or the third dielectric layer are/is subjected to the patterning process, retaining a portion of the dielectric layer and/or the third dielectric layer covering the side surface of the optical isolation portion. When the portion of only one of the dielectric layer and the third dielectric layer covering the side surface of the optical isolation portion is retained, the material of the second dielectric portion may be the same with that of one of the main body portion 7036 and the covering portion 7037 of the dielectric portion 7031. When the portions of both the dielectric layer and the third dielectric layer covering the side surface of the optical isolation portion are retained, the material of the second dielectric portion can include the materials of both the main body portion 7036 and the covering portion 7037 of the dielectric portion 7031. That is, the material of the second dielectric portion can be the same with that of one of the main body portion 7036 and the covering portion 7037 of the dielectric portion 7031, or include the materials of both.

In addition, similarly, the second dielectric portion may be formed in the following manner: after forming the optical isolation portion 7031, separately forming the second dielectric layer on the optical isolation portion 7031 and the semiconductor substrate 701, and patterning the second dielectric layer, to remove the portion of the second dielectric layer above the photosensitive element 702 and the portion thereof above the optical isolation portion 7031, and retain the portion of the second dielectric layer covering the side surface of the optical isolation portion 7031, thereby forming the second dielectric portion. Similarly, since the second dielectric layer is formed separately, its material can be the same with or different from the materials of the main body portion 7036 and the covering portion 7037 of the dielectric portion 7032. Therefore, the material of the second dielectric portion can be determined according to the actual needs, which increases flexibility of the design.

FIG. 8 is a schematic diagram illustrating a structure of a semiconductor device according to another embodiment of this disclosure, wherein the top portion of the dielectric portion has a triangular cross section.

Similar to FIG. 2, the semiconductor device 800 shown in FIG. 8 also comprises a semiconductor substrate 801, an array of photosensitive elements 802 formed in the semiconductor substrate 801, and a grid 803 formed on the substrate 801 and the photosensitive elements 802. The grid 803 according to the embodiment of this disclosure comprises an optical isolation portion 8031 and a dielectric portion 8032 above the optical isolation portion 8031. Unlike the structure shown in FIG. 2, in this embodiment, the top portion of the dielectric portion 8032 has a triangular cross section, instead of a trapezoidal cross section. In addition, an optional optical material 804 can be filled in the opening, and above the optical material 804, the semiconductor device 800 may further comprise an optional microlens 805.

In this embodiment, the patterning process described in the above embodiments can also be adopted to form the triangular cross section at the top portion of the dielectric portion. However, as compared to the formation of the triangular cross section, the formation of trapezoidal cross section can retain a portion of the top surface of the dielectric portion 2032, which facilitate the support of the mask, the stability of the process, and the formation of the tilted sidewall of the dielectric portion.

In the embodiments of this disclosure, the semiconductor device can utilize various image sensor technologies, such as CMOS, CCD, etc. In addition, in the embodiments of this disclosure, the semiconductor device may utilize a front side illumination (FSI) image sensor technique or a back side illumination (BSI) image sensor technique. A front side illumination (FSI) image sensor refers to an image sensor in which circuit wirings and so on are in front of the photosensitive element in the incident light direction, that is, the circuit wirings and so on are between the photosensitive element and the imaging object. In contrast, a back side illumination (BSI) image sensor refers to an image sensor in which circuit wirings and son on are behind the photosensitive element in the incident light direction, that is, the photosensitive element is between the circuit wirings and son on and the imaging object. In other words, unlike the front side illumination image sensor, in the back side illumination image sensor, wirings and other components which may affect the reception of radiation are basically in the front of the substrate, and light enters from the back of the substrate.

Therefore, although not shown in the figures, when the semiconductor device according to the embodiments of this disclosure utilizes the back side illumination image sensor technology, a conductive wiring portion is further comprised below the photosensitive element or in the same layer with the photosensitive element in the figures. In addition, although not shown in the figures, when the semiconductor device according to the embodiments of this disclosure utilizes the front side illumination image sensor technology, a conductive wiring portion is further comprised above the photosensitive element in the figures. The conductive wiring portion consists of one of more layers of conductive material layers, wherein the conductive material can be selected from for example: metal, metal alloy, conductive metal compound. Examples of the metal include titanium, tungsten or aluminum, etc.

Regardless of whether the semiconductor device according to the embodiments of this disclosure adopts the back side illumination image sensor technology or the front side illumination image sensor technology, it can attain the technical effects of improving utilization of the incident light, and thereby improving quantum efficiency, signal-to-noise ratio of the image sensor and so on. However, as compared to the front side illumination image sensor, the technical effects of improving utilization of the incident light, quantum efficiency and signal-to-noise ratio are more important to the back side illumination image sensor, therefore, when the semiconductor device according to the embodiments of this disclosure adopts the back side illumination image sensor technology, it can produce more notable advantages than the back side illumination image sensor in the related technologies.

In addition, in the embodiments of this disclosure, one or more layers of insulating layers and/or reflective layers can be arranged above the substrate and the photosensitive element, and between the substrate and the grid, for the purpose of protecting the semiconductor substrate and the photosensitive elements, increasing an amount of light incidence, etc. These layers can be made from light-transmissive materials such as (but not limited to) various high k mediums, silicon oxides, silicon nitrides, silicon nitrogen oxide or oxynitride, etc. These materials can be produced for example by various preparation methods, including but not limited to, physical vapor deposition (PVD), chemical vapor deposition (CVD), atomic layer deposition (ALD), spraying, spin coating, or a combination thereof.

Although two-pixels (photosensitive elements) placed side by side are described and illustrated as an example in the accompanying drawings of this disclosure, a person skilled in the art could understand that, the pixel array (array of photosensitive elements) in the semiconductor device of this disclosure can be arranged in a planar direction of the substrate. That is, the portions of the semiconductor device shown in the accompanying drawings of this disclosure can be arranged repeatedly in the planar direction of the substrate to obtain a predetermined number of pixels.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, a person skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

1. A semiconductor device, comprising:
an array of photosensitive elements; and
a grid arranged on the array of photosensitive elements, defining an opening for receiving light respectively for each photosensitive element, and optically isolating each photosensitive element from adjacent photosensitive elements thereof,
wherein the grid comprises an optical isolation portion and a dielectric portion above the optical isolation portion, wherein the dielectric portion defines a sidewall tilted at an angle toward an outer side of the opening.

2. The semiconductor device according to claim 1, wherein a cross section of a top portion of the dielectric portion is a triangle or trapezoid.

3. The semiconductor device according to claim 1, further comprising an optical material filled in the opening of the grid.

4. The semiconductor device according to claim 3, wherein at an interface between the optical material and the sidewall, a refractive index of the optical material is greater than a refractive index of a material of the dielectric portion, and a tilt angle of the sidewall is configured such that light incident from outside of the semiconductor device onto the interface is totally reflected toward the photosensitive element.

5. The semiconductor device according to claim 1, wherein the optical isolation portion is made of an opaque material.

6. The semiconductor device according to claim 1, wherein the grid further comprises a second dielectric portion covering a side surface of the optical isolation portion.

7. The semiconductor device according to claim 6, wherein
the dielectric portion and the second dielectric portion are made of the same dielectric material, or
the dielectric portion and the second dielectric portion are made of different dielectric materials.

8. The semiconductor device according to claim 1, wherein the dielectric portion comprises a main body portion and a covering portion, wherein the covering portion covers a surface of the main body portion, and the covering portion and the main body portion are made of different dielectric materials.

9. The semiconductor device according to claim 8, wherein the grid further comprises a second dielectric portion covering a side surface of the optical isolation portion, and
the second dielectric portion and one of the main body portion and the covering portion of the dielectric portion are made of the same dielectric material, or
the second dielectric portion is made of a different material from both the main body portion and the covering portion of the dielectric portion, or
the second dielectric portion comprises materials of both the main body portion and the covering portion of the dielectric portion.

10. A method of manufacturing the semiconductor device according to claim 1, comprising:
forming the array of photosensitive elements in a semiconductor substrate; and
forming the grid on the array of photosensitive elements, wherein the grid defines the opening for receiving light respectively for each photosensitive element, and optically isolates each photosensitive element from adjacent photosensitive elements thereof,
wherein the grid comprises the optical isolation portion and the dielectric portion above the optical isolation portion, wherein the dielectric portion defines the sidewall tilted at an angle toward the outer side of the opening.

11. The method according to claim 10, wherein forming the grid on the array of photosensitive elements comprises:
forming an optical isolation material layer on the semiconductor substrate;
subjecting the optical isolation material layer to a patterning process to remove a portion of the optical isolation material layer above the photosensitive element, thereby forming the optical isolation portion, wherein a pattern of the optical isolation portion corresponds to a pattern of the grid and defines the opening;
forming a dielectric layer on the optical isolation material layer and the semiconductor substrate; and
subjecting the dielectric layer to a patterning process to remove a portion of the dielectric layer above the photosensitive element, and remain a portion thereof above the optical isolation portion and form the sidewall tilted at an angle toward the outer side of the opening, to thereby form the dielectric portion.

12. The method according to claim 11, wherein the patterning process to which the dielectric portion is subjected makes a cross section of a top portion thereof become a triangle or trapezoid.

13. The method according to claim 10, further comprising a step of: filling an optical material in the opening of the grid.

14. The method according to claim 13, wherein at an interface between the optical material and the sidewall, a refractive index of the optical material is greater than a refractive index of a material of the dielectric portion, and the tilt angle of the sidewall is configured such that the light incident from outside of the semiconductor device onto the interface is totally reflected toward the photosensitive element.

15. The method according to claim 10, wherein the optical isolation portion is made of an opaque material.

16. The method according to claim 11, wherein forming the grid on the array of photosensitive elements further comprises:
when subjecting the dielectric layer to a patterning process, retaining a portion of the dielectric layer covering a side surface of the optical isolation portion, thereby forming a second dielectric portion.

17. The method according to claim 11, wherein forming the grid on the array of photosensitive elements further comprises:
after forming the optical isolation portion, forming a second dielectric layer on the optical isolation portion and the semiconductor substrate, and
subjecting the second dielectric layer to a patterning process, to remove a portion of the second dielectric layer above the photosensitive element and a portion thereof above the optical isolation portion, and retain a portion of the second dielectric layer covering a side surface of the optical isolation portion, thereby forming a second dielectric portion.

18. The method according to claim 11, wherein
subjecting the dielectric layer to a patterning process comprises: removing the portion of the dielectric layer above the photosensitive element and retaining the portion thereof above the optical isolation portion, thereby forming a main body portion of the dielectric portion, and
forming the grid on the array of photosensitive elements further comprises:
after forming the main body portion of the dielectric portion, forming a third dielectric layer on the semiconductor substrate and the main body portion of the dielectric portion; and
subjecting the third dielectric layer to a patterning process to remove a portion of the third dielectric layer above the photosensitive element and retain a portion thereof above the main body portion of the dielectric portion, thereby forming a covering portion of the dielectric portion,
wherein the covering portion and the main body portion of the dielectric portion are made of different dielectric materials.

19. The method according to claim 18, wherein forming the grid on the array of photosensitive elements further comprises:
when subjecting the dielectric layer and/or the third dielectric layer to a patterning process, retaining a portion of the dielectric layer and/or the third dielectric layer covering a side surface of the optical isolation portion, thereby forming the second dielectric portion.

20. The method according to claim 18, wherein forming the grid on the array of photosensitive elements further comprises:
after forming the optical isolation portion, forming a second dielectric layer on the optical isolation portion and the semiconductor substrate, and
subjecting the second dielectric layer to a patterning process, to remove a portion of the second dielectric layer above the photosensitive element and a portion thereof above the optical isolation portion, and retain a portion of the second dielectric layer covering the side surface of the optical isolation portion, thereby forming a second dielectric portion,
wherein the second dielectric portion and one of the main body portion and the covering portion of the dielectric portion are made of the same dielectric material, or
the second dielectric portion is made of a different material from both the main body portion and the covering portion of the dielectric portion, or
the second dielectric portion comprises materials of both the main body portion and the covering portion of the dielectric portion.
